(19) United States
(12) Patent Application Publication
(10) Pub. No.: US 2026/0269189 A1
(43) Pub. Date: Sep. 10, 2026

(54) APPARATUS FOR MANUFACTURING SEMICONDUCTOR STRUCTURES AND METHOD FOR MANUFACTURING SEMICONDUCTOR STRUCTURES

(71) Applicant: TAIWAN SEMICONDUCTOR MANUFACTURING COMPANY LTD., HSINCHU (TW)

(72) Inventor: HSING-PIAO HSU, TAOYUAN CITY (TW)

(21) Appl. No.: 19/019,548

(22) Filed: Jan. 14, 2025

(51) Int. Cl. H01J 37/32

(52) U.S. Cl. CPC H01J 37/32449; H01J 37/32522; H01J 2237/3365

(57) ABSTRACT

An apparatus for manufacturing a semiconductor structure includes a processing chamber configured to form a plasma; a first gas supply system configured to supply a first gas to the processing chamber; a gas conduit disposed between and in communication with the processing chamber and the first gas supply system; and a heating system disposed on the gas conduit and configured to heat the first gas flowing through the gas conduit and to provide a first heated gas to the processing chamber.

### BACKGROUND

Ion implantation (IMP) is widely used for creating regions of various dopant concentrations during the manufacture of semiconductor structures. In an IMP process, ions are accelerated to bombard a solid target (e.g., a substrate or a film), thereby changing properties (e.g., physical, chemical, and/or electrical properties) of the target. For example, in a complementary metal-oxide semiconductor (CMOS) device, regions of different dopant concentrations can be formed by IMP. A gas supply system of an IMP tool provides gas for the ions.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, dimensions of the various features may be arbitrarily increased or reduced for clarity of discussion.

FIG. 1 is a schematic view of an apparatus in accordance with some embodiments of the present disclosure.

FIG. 2 is a schematic view of an apparatus in accordance with some embodiments of the present disclosure.

FIG. 3 is a schematic view of an apparatus in accordance with some embodiments of the present disclosure.

FIG. 4 is a schematic view of an apparatus in accordance with some embodiments of the present disclosure.

FIG. 5 is a schematic view of an apparatus in accordance with some embodiments of the present disclosure.

FIG. 6 is a schematic view of an apparatus in accordance with some embodiments of the present disclosure.

FIG. 7 is a schematic view of an apparatus in accordance with some embodiments of the present disclosure.

FIG. 8 is a schematic view of an apparatus in accordance with some embodiments of the present disclosure.

FIG. 9 is a flowchart of a method for manufacturing a semiconductor structure in accordance with some embodiments of the present disclosure.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features are not in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “upper,” “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, although the terms such as “first,” “second” and “third” describe various elements, components, regions, layers and/or sections, these elements, components, regions, layers and/or sections should not be limited by these terms. These terms may be only used to distinguish one element, component, region, layer or section from another. The terms such as “first,” “second” and “third” when used herein do not imply a sequence or order unless clearly indicated by the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the normal deviation found in the respective testing measurements. Also, as used herein, the terms “substantially,” “approximately” and “about” generally mean within a value or range that can be contemplated by people having ordinary skill in the art. Alternatively, the terms “substantially,” “approximately” and “about” mean within an acceptable standard error of the mean when considered by one of ordinary skill in the art. People having ordinary skill in the art can understand that the acceptable standard error may vary according to different technologies.

Other than in the operating/working examples, or unless otherwise expressly specified, all of the numerical ranges, amounts, values and percentages such as those for quantities of materials, durations of time, temperatures, operating conditions, ratios of amounts, and the likes thereof disclosed herein should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as from one endpoint to another endpoint or between two endpoints. All ranges disclosed herein are inclusive of the endpoints, unless specified otherwise.

An ion implantation (IMP) system is a semiconductor fabrication apparatus used to implant one or more dopant elements into a semiconductor wafer to form doped regions at desired depths in the semiconductor wafer. These dopants can enable the device or structure to have desired properties, which are essential for various applications. For example, source and drain regions of a CMOS device can be formed by performing ion implantations on the substrate. The dopant elements are introduced into the semiconductor wafer with an ion beam generated and controlled by the IMP system. To produce the ion beam, an implant gas or feed material with a desired dopant material is introduced into an ion source, where a high energy is applied to ionize the implant gas or feed material to form the ion beam. An accelerating electric field is provided by IMP electrodes to extract and direct the ion beam toward the semiconductor wafer.

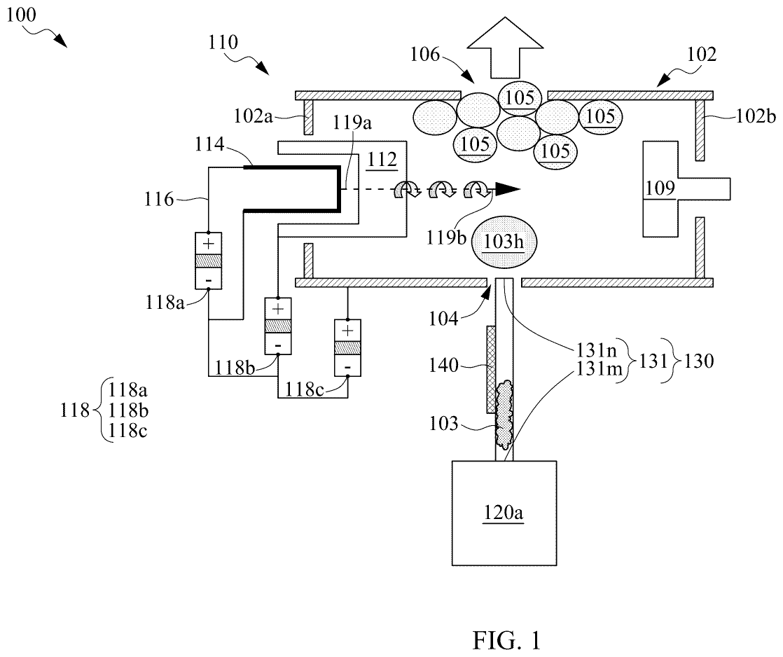

FIG. 1 is a schematic view of an apparatus 100 for manufacturing a semiconductor structure in accordance with some embodiments of the present disclosure. Referring to FIG. 1, the apparatus 100 for manufacturing a semiconductor structure includes a processing device 110, a first gas supply system 120a, a gas regulating system 130, and a heating system 140.

In some embodiments, the processing device 110 is configured to extract ions 105 and includes a processing chamber 102. The processing chamber 102 is configured to receive at least one implant gas or feed material, such as a first gas 103, and is configured to form the ions 105. In some embodiments, the ions 105 include plasma comprising ionized implant gas or feed material. In some embodiments, the processing chamber 102 includes at least one inlet 104 for receiving the first gas 103, and an outlet 106 providing an exit pathway for the ions 105. In some embodiments, the inlet 104 is disposed on or through a sidewall of the processing chamber 102. In some embodiments, the apparatus 100 further includes an implant tool (not shown) to use the ions 105 for manufacturing a semiconductor structure on a targeted semiconductor wafer, wherein the implant tool is coupled to the outlet 106.

Examples of the first gas 103 include but are not limited to phosphine (PH₃), boron trifluoride (BF₃), arsine (AsH₃), germanium tetrafluoride (GeF₄), silicon tetrafluoride (SiF₄), nitrogen (N₂), oxygen (O₂), carbon monoxide (CO), carbon dioxide (CO₂), hydrogen (H₂), xenon dihydride (XeH₂), aluminum chloride (AlCl₃), selenium dioxide (SeO₂), ytterbium (Yb), gallium(III) fluoride (GaF₃), indium(III) chloride (InCl₃), antimony trioxide (Sb₂O₃), hafnium(IV) chloride (HfCl₄), titanium (Ti), hydrogen sulfide (H₂S) and any other dopant precursors suitable for doping a semiconductor wafer. Depending on the desired doping type of the targeted semiconductor wafer, different implant gases or feed materials can be selected as the first gas 103.

In some embodiments, the processing device 110 is an IMP system including a source head. In some embodiments, the processing device 110 includes a cathode 112, a filament 114, power supply units 118a, 118b, 118c, and conductive wires 116. In some embodiments, the cathode 112 and the filament 114 in the processing chamber 102 of the processing device 110 generate hot electrons, and the implant gas or feed material in the processing chamber 102 is hit by the hot electrons to dissociate molecules of the implant gas or feed material into ions and to generate plasma. Various factors can cause damage to or ruptures of the filament 114 and the cathode 112. When the filament 114 or the cathode 112 is damaged, the source head needs to be shut down for replacement of the filament 114 and the cathode 112 before the source head can continue to operate. Furthermore, when the implant gas or the feed material has a greater binding energy, an energy required to cause the dissociation is greater, and a work function required by the source head is also greater, which can easily lead to the damage to or the ruptures of the filament and the cathode. A purpose of the present disclosure includes extending a service life of the source head and mitigating device degradation. Accordingly, an improved apparatus for manufacturing a semiconductor structure and an improved method for manufacturing a semiconductor structure are needed.

In some embodiments, the cathode 112, the filament 114 and the processing chamber 102 may be connected to power supply units 118a, 118b, 118c though the conductive wires 116. In some embodiments, the power supply unit 118a applies a voltage to excite and heat the filament 114 so that the filament 114 emits primary electrons 119a, and the power supply unit 118c applies a voltage to the cathode 112 so that the cathode 112 emits secondary electrons 119b toward the first gas 103 when the primary electrons 119a hit the cathode 112. In some embodiments, the cathode 112 is biased at a voltage from a DC supplier 118b. In some embodiments, the filament 144 is heated by a voltage applied thereon.

In some embodiments, the cathode 112 is disposed on a first sidewall 102a of the processing chamber 102, and a repeller 109 is disposed on a second sidewall 102b opposite to the first sidewall 102a. The repeller 109 is configured to confine secondary electrons 119b in the processing chamber 102 and reflect them back toward the cathode 112, causing the secondary electrons 119b to travel repeatedly in the processing chamber 102 in helical paths from the cathode 112 to the repeller 109, such that the secondary electrons 119b collide with molecules of the first gas 103 and generate the ions 105 that form the plasma. In other words, the dopant molecules of the first gas 103 are ionized to form plasma comprising dopant ions, radicals and other species. For example, AsH₃ molecules struck by electrons produce ions such as As⁺, As₂⁺ and AsH₂⁺.

In some embodiments, the inlet 104 is disposed between the first sidewall 102a and the second sidewall 102b, and the outlet 106 is disposed opposite to the inlet 104.

In some embodiments, a larger effective surface for heating may facilitate emission of the secondary electrons 119b, therefore generating a desired ion beam based on Richardson's Law:

$$J = {A}_{G} {T}^{2} {e}^{- W / kT}$$

wherein J is emission current density, T is temperature (K) of a metal of the cathode 112, W is a work function of the metal of the cathode 112, k is the Boltzmann constant, and AG is a parameter.

However, the cathode 112 is a consumable component of ion sputtering. The greater the work required by the cathode 112, the easier it is to damage the cathode 112. To change the cathode 112, the processing device 110 needs to be shut down, which adversely impacts fabrication time. In addition, as the cathode 112 need to be replaced often, processing costs of the processing device 110 are increased by frequent shutdowns. Embodiments of the present disclosure, among other things, describe an apparatus, system, and method for manufacturing a semiconductor structure with an ion beam. Although the embodiments presented below are described in the context of a processing device 110 configured to form a plasma, the embodiments can be used in other fabrication tools without departing from the scope and spirit of the present disclosure. If the work needed to produce a particular ion beam is provided by another component, the service life of the cathode 112 may be increased.

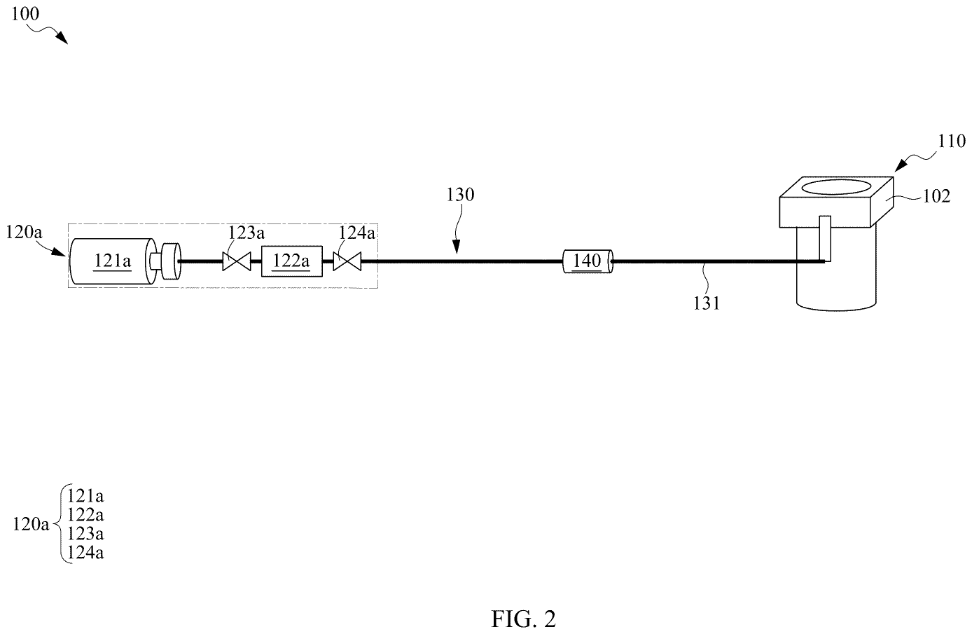

FIG. 2 is a schematic view of an apparatus in accordance with some embodiments of the present disclosure. In some embodiments, referring to FIGS. 1 and 2, the first gas supply system 120 a is configured to supply the first gas 103 to the processing chamber 102, and the gas regulating system 130 is configured to regulate an amount and a timing of the first gas 103 flowing into the processing chamber 102. In some embodiments, a first gas conduit 131 of the gas regulating system 130 is disposed between and in communication with the processing chamber 102 and the first gas supply system 120a. In some embodiments, the first gas conduit 131 has a first end 131m coupled to the first gas supply system 120a and a second end 113n opposite to the first end 131m and coupled to the inlet 104 of the processing chamber 102. The second end 131n is distal to the first gas supply system 120a.

In some embodiments, the first gas supply system 120a includes a first gas container 121a with a first gas container valve 123a, a first flow controller 122a and a first gate valve 124a, and the first gas 103 is provided to the processing chamber 102 by the first gas supply system 120a at a certain flow rate controlled by the first gas container valve 123a, the first flow controller 122a and the first gate valve 124a.

In some embodiments, the first gas container 121a is configured to provide the first gas 103, such as PH₃, BF₃, AsH₃, GeF₄, SiF₄, N₂, O₂, CO, CO₂, H₂, XeH₂, AlCl₃, SeO₂, Yb, GaF₃, InCl₃, Sb₂O₃, HfCl₄, Ti, H₂S or a mixture thereof, and the first gas container valve 123a is configured to control a flow of the first gas 103 from the first gas container 121a. The first gas container valve 123a can be a manually-controlled valve or a computer-controlled valve and can remain open after the first gas container 121a is connected to first gas conduit 131. The first flow controller 122a can limit or regulate the flow rate of the first gas 103 from the first gas container 121a. The first gate valve 124a can control the first gas 103 flowing from the first flow controller 122a to the processing chamber 102. In some embodiments, the first flow controller 122a connects to the first gas source 121a through the first gas conduit 131. In some embodiments, the first flow controller 122a is a mass flow controller (MFC).

In some embodiments, the first flow controller 122a is configured to control the flow of the first gas 103 flowing from the 121a to the heating system 140 through the first gas conduit 131. The first flow controller 122a may be, for example, a proportional valve, a modulating valve, a needle valve, or any combinations thereof, and so on.

In some embodiments, the first flow controller 122a includes an electrically adjustable valve that provides continuous or multiple stepwise adjustment of the flow of the first gas 103 output by the first flow controller 122a. In some embodiments, the first flow controller 122a includes a mass flow sensor and an adjustable valve to provide a precise feedback-controlled flow of the process gas out of the first flow controller 122a. The flow output of the first flow controller 122a is adjustable between zero (or some minimum) flow rate and a maximum flow rate, with the flow rate being set by an electrical setpoint input against which the reading of the mass flow sensor is compared to generate the error signal used in feedback control of the flow rate.

In some embodiments, closing of first gate valve 124a can prevent other gases in the first gas conduit 131 to flow to the first gas container 121a and the first flow controller 122a when the first gas 103 in the first gas container 121a and the first flow controller 122a is not in use. In some embodiments, the first flow controller 122a, the first gas container valve 123a and the first gate valve 124a can be controlled by a control unit (not shown) and can be opened and closed at a same time (or at different times) when providing the first gas 103 from the first gas container 121a.

In some embodiments, the heating system 140 is configured to provide a first heated gas 103h to the processing chamber 102. In some embodiments, the heating system 140 is configured to heat the first gas 103 before the first gas 103 flows into the processing device 110. In some embodiments, the heating system 140 is disposed between the first flow controller 122a and the processing chamber 102. In some embodiments, a temperature of the heated gas 103 h may be between approximately 500° C. and approximately 1,000° C., but the disclosure is not limited thereto.

Compared to the first gas 103, the first heated gas 103h has lower binding energy and is easier to dissociate in the processing chamber 102. Compared to the processing device without a heater to pre-heat the gas flowing into the processing device, a power consumption of the processing device 110 of the present disclosure can be reduced by at least 15% and by as much as 45%, and a service life of the processing device 110 of the present disclosure can be prolonged by at least 15%. For example, to break an As—H bonding requires 274 kJ/mole, to break a P—H bonding requires 297 kJ/mole, and to break a B—F bonding requires an even greater energy of 757 kJ/mole. In the present disclosure, the heating system 140 provides a portion of the energy to break the bonding by heating the first gas 103, and the processing device 110 provides the remaining energy of breaking the bonding of the first heated gas 103h, thereby the power consumption of the processing device 110 of the present disclosure can be reduced and the service life of the processing device 110 can be prolonged.

In some embodiments, the heating system 140 and the processing device 110 are separated from each other, and the first gas conduit 131 allows the first gas 103 to flow through the heating system 140 before flowing into the processing chamber 102. In some embodiments, the heating system 140 is disposed on the gas regulating system 130. In some embodiments, the heating system 140 is attached to the first gas conduit 131. In some embodiments, the heating system 140 is concentrically provided with respect to the first gas conduit 131. Since the heating system 140 and the processing device 110 are independent of each other and the heating system 140 is located outside the processing chamber 102, the heating system 140 can be easily and cost-effectively replaced and repaired without shutting down the processing device 110 during repairs.

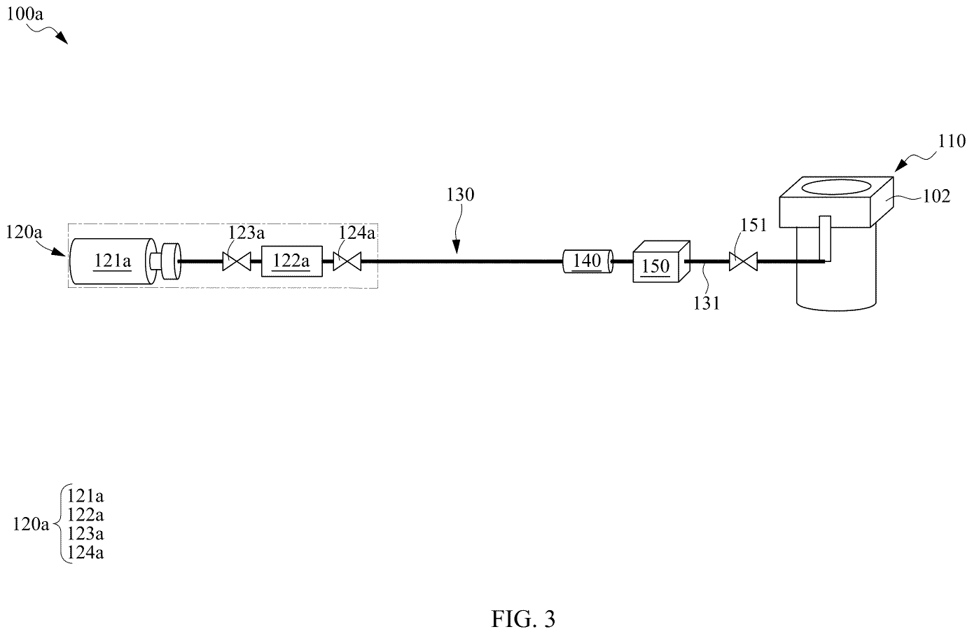

FIG. 3 is a schematic view of an apparatus 100a in accordance with some embodiments of the present disclosure. In some embodiments, a first gas supply system 120a, a gas regulating system 130, a heating system 140 and a processing device 110 illustrated in FIG. 3 are similar to the first gas supply system 120a, the gas regulating system 130, the heating system 140 and the processing device 110 illustrated in FIGS. 1 and 2, respectively, except that the apparatus 100 a shown in FIG. 3 further includes a storage tank 150 disposed between the processing chamber 102 and the heating system 140. In some embodiments, the storage tank 150 is in communication with the first gas conduit 131 and is configured to store the first heated gas 103h. In some embodiments, a temperature of the first heated gas 103h depends on a gas flow rate or a heating time. In some embodiments, the first heated gas 103h having different temperatures is collected and mixed in the storage tank 150 therein, and the first heated gas 103h flowing into the processing chamber 102 is provided from the storage tank 150 at a predetermined temperature. In some embodiments, a source head valve 151 is disposed between the storage tank 150 and the processing device 110. When the source head valve 151 is in an open configuration, the first heated gas 103h may flow into the processing chamber 102.

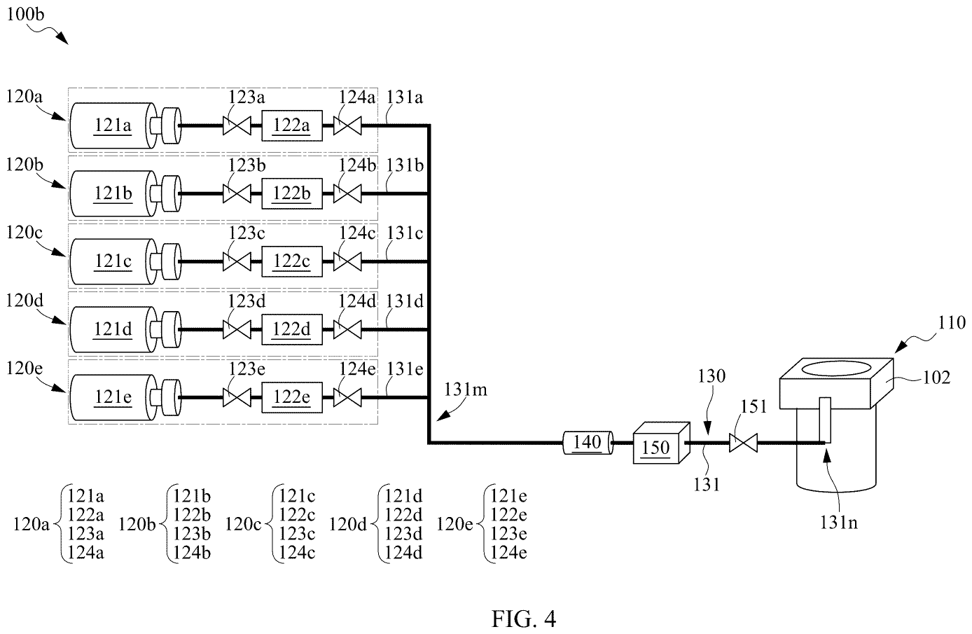

FIG. 4 is a schematic view of an apparatus in accordance with some embodiments of the present disclosure. In some embodiments, an apparatus 100b shown in FIG. 4 is provided. A first gas supply system 120a, a gas regulating system 130, a heating system 140 and a processing device 110 illustrated in FIG. 4 are similar to the first gas supply system 120a, the gas regulating system 130, the heating system 140 and the processing device 110 illustrated in FIG. 3, respectively, except that the apparatus 100b shown in FIG. 4 further includes a second gas supply system 120b configured to supply a second gas (not shown) to a first gas conduit 131, and the gas regulating system 130 further includes a first guiding channel 131a and a second guiding channel 131b.

In some embodiments, the second gas supply system 120b is connected to the gas regulating system 130 and configured to provide a second gas to the first gas conduit 131, and the first gas conduit 131 is configured to provide a second heated gas (not shown) to the processing chamber 102. The gas regulating system 130 is configured to regulate the second gas and the second heated gas flowing into the processing chamber 102.

In some embodiments, a first end 131m of the first gas conduit 131 is coupled to the first guiding channel 131a and the second guiding channel 131b, and a second end 131n of the first gas conduit 131 is coupled to a processing chamber 102 and distal to the first gas supply system 120a and the second gas supply system 120b. In some embodiments, the first guiding channel 131a is connected to a first end 131m of the first gas conduit 131 and the first gas supply system 120a. In some embodiments, the second guiding channel 131b is connected to the first end 131m of the first gas conduit 131 and the second gas supply system 120b.

In some embodiments, the second gas supply system 120b includes a second gas container 121b with a second gas container valve 123b, a second flow controller 122b and a second gate valve 124b, and the second gas is provided to the first gas conduit 131 by the second gas supply system 120b at a certain flow rate controlled by the second gas container valve 123b, the second flow controller 122b and the second gate valve 124b. In some embodiments, a configuration of the second gas supply system 120b is similar to a configuration of the first gas supply system 120a.

In some embodiments, the second gas container 121b is configured to provide the second gas, such as PH₃, BF₃, AsH₃, GeF₄, SiF₄, N₂, O₂, CO, CO₂, H₂, XeH₂, AlCl₃, SeO₂, Yb, GaF₃, InCl₃, Sb₂O₃, HfCl₄, Ti, H₂S or a mixture thereof. The first gas 103 and the second gas may be similar or different. The second gas container valve 123b is configured to control a flow of the second gas from the second gas container 121b. The second gas container valve 123b can be a manually-controlled valve or a computer-controlled valve and can remain open after the second gas container 121b is connected to the first gas conduit 131. The second flow controller 122b can limit or regulate a flow rate of the second gas from the second gas container 121b. The second gate valve 124b can control the second gas flowing from the second flow controller 122b to the processing chamber 102. In some embodiments, the second flow controller 122b connects to the second gas source 121b through the first gas conduit 131. In some embodiments, the second flow controller 122b is an MFC. In some embodiments, a configuration of the second flow controller 122b is similar to a configuration of the first flow controller 122a.

In some embodiments, closing of the second gate valve 124b can prevent other gases in the first gas conduit 131 from flowing to the second gas container 121b and the second flow controller 122b when the second gas in the second gas container 121b and the second flow controller 122b is not in use. In some embodiments, the second flow controller 122b, the second gas container valve 123b and the second gate valve 124b can be controlled by a control unit (not shown) and can be opened and closed at a same time (or at different times) when providing the second gas 103 from the second gas container 121a.

In some embodiments, the first gas 103 from the first gas supply system 120a and the second gas from the second gas supply system 120b are mixed in the first end 131m of the first gas conduit 131. In some embodiments, a mixture of the first gas and the second gas is formed in the first gas conduit 131 when the first flow controller 122a, the second flow controller 122b, the first gas container valve 123a, the second gas container valve 123b, the first gate valve 124a and the second gate valve 124b are opened. A ratio of the first gas 103 to the second gas can be determined by the flow rates of the first gas 103 and the second gas, which are controlled by the first flow controller 122a and the second flow controller 122b, respectively.

In some embodiments, the heating system 140 is configured to heat the first gas 103 and the second gas flowing through the first gas conduit 131 and configured to provide the first heated gas 103h and the second heated gas to the processing chamber 102. In some embodiments, a storage tank 150 is disposed between the processing chamber 102 and the heating system 140, wherein the storage tank 150 is in communication with the first gas conduit 131 and configured to mix the first heated gas 103h and the second heated gas therein. A temperature of the second heated gas in the storage tank 150 is similar to a temperature of the first heated gas 103h in the storage tank 150. In some embodiments, the storage tank 150 is in communication with the gas regulating system 130 and configured to receive the first heated gas 103h and the second heated gas, and configured to provide a mixture of the first heated gas 103h and the second heated gas to the processing chamber 102.

According to the present disclosure, multiple gas supply systems such as the first gas supply system 120a and the second gas supply system 120b can be implemented. A person ordinarily skilled in the art would readily understand that any suitable number of the gas supply systems may alternatively be utilized, and such arrangements are within the spirit and scope of the present disclosure.

In some embodiments, the apparatus 100b further includes a third gas supply system 120c, a fourth gas supply system 120d and a fifth gas supply system 120e configured to supply a third gas (not shown), a fourth gas (not shown) and a fifth gas (not shown), respectively, to the first gas conduit 131. Structures and configurations of the third gas supply system 120c, the fourth gas supply system 120d and the fifth gas supply system 120e are similar to those of the first gas supply system 120a, and each of the gas supply systems can independently provide gas or stop supplying gas to the first gas conduit 131. The first gas supply system 120a, the second gas supply system 120b, the third gas supply system 120c, the fourth gas supply system 120d and/or the fifth gas supply system 120e are configured to provide same or different gases to the processing device 110.

In some embodiments, all the gases from the first gas supply system 120a, the second gas supply system 120b, the third gas supply system 120c, the fourth gas supply system 120d and/or the fifth gas supply system 120e are mixed in the first gas conduit 131 to form a mixture, and the heating system 140 is configured to heat the mixture. In some embodiments, a third guiding channel 131c is connected to the first end 131m of the first gas conduit 131 and the third gas supply system 120c. In some embodiments, a fourth guiding channel 131d is connected to the first end 131m of the first gas conduit 131 and the fourth gas supply system 120d. In some embodiments, a fifth guiding channel 131e is connected to the first end 131m of the first gas conduit 131 and the fifth gas supply system 120e.

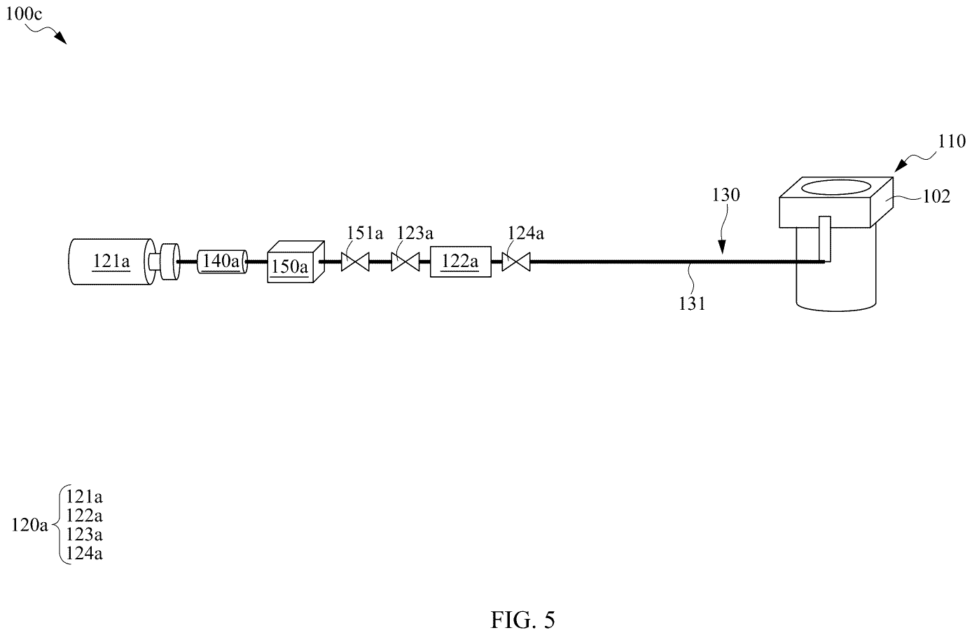

FIG. 5 is a schematic view of an apparatus in accordance with some embodiments of the present disclosure. In some embodiments, an apparatus 100c shown in FIG. 5 is provided.

A first gas supply system 120a, a gas regulating system 130, a first heating system 140a and a processing device 110 illustrated in FIG. 5 are similar to the first gas supply system 120a, the gas regulating system 130, the heating system 140 and the processing device 110 illustrated in FIG. 3, respectively, except that the first heating system 140a of the apparatus 100c shown in FIG. 5 is disposed between the first gas source 121a and the first flow controller 122a. In some embodiments, a first storage tank 150a is disposed between the first heating system 140a and the first flow controller 122a. In some embodiments, the first storage tank 150a is configured to store a first heated gas 103h. In some embodiments, a first source head valve 151a is disposed between the first storage tank 150a and the first flow controller 122a, and the first flow controller 122a is configured to control the flow of the first heated gas 103h through the first gas conduit 131. The first flow controller 122a can limit or regulate a flow rate of the first heated gas 103h from the first storage tank 150a.

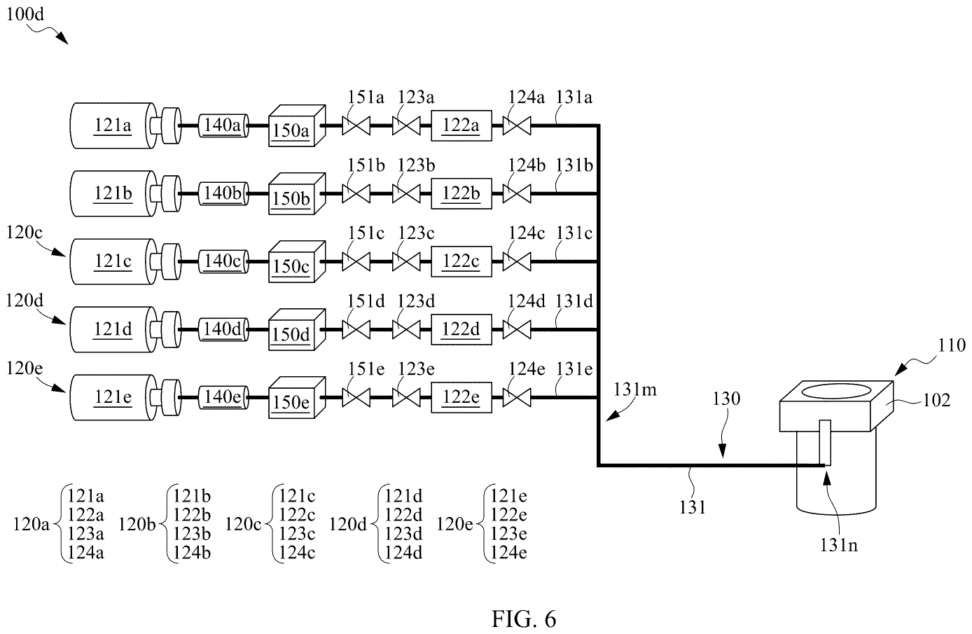

FIG. 6 is a schematic view of an apparatus in accordance with some embodiments of the present disclosure. In some embodiments, an apparatus 100d shown in FIG. 6 is provided.

A first gas supply system 120a, a gas regulating system 130, a first heating system 140a, a first storage tank 150a and a processing device 110 illustrated in FIG. 6 are similar to the first gas supply system 120a, the gas regulating system 130, the first heating system 140a, the first storage tank 150a, and the processing device 110 illustrated in FIG. 5, respectively, except that the apparatus 100d shown in FIG. 6 further includes a second gas supply system 120b, and a second heating system 140b is disposed between a second gas source 121b and a second flow controller 122b.

In some embodiments, the apparatus 100d further includes a second storage tank 150b disposed between the second heating system 140b and the second flow controller 122b. In some embodiments, a second source head valve 151b is disposed between the second storage tank 150b and the second flow controller 122b.

In some embodiments, the second storage tank 150b is configured to store a second heated gas. A temperature of the second heated gas is similar to or different from a temperature of the first heated gas 103h. In some embodiments, the temperature of the second heated gas is different from the temperature of the first heated gas 103h. In some embodiments, the second flow controller 122b is configured to control a flow of the second heated gas into the first gas conduit 131. The second flow controller 122b can limit or regulate the flow rate of the second heated gas from the second storage tank 150b.

In some embodiments, the first heated gas 103h from first flow controller 122a and the second heated gas from the second flow controller 122b are mixed in the first gas conduit 131. In some embodiments, a mixture of the first heated gas 103h and the second heated gas is formed in the first gas conduit 131 when the first flow controller 122a, the second flow controller 122b, a first gas container valve 123a, a second gas container valve 123b, a first gate valve 124a and a second gate valve 124b are opened. A ratio of the first heated gas 103h to the second heated gas can be determined by the flow rates of the first heated gas 103h and the second heated gas, which are controlled by the first flow controller 122a and the second flow controller 122b, respectively.

In some embodiments, a first end 131m of the first gas conduit 131 is coupled to a first guiding channel 131a and a second guiding channel 131b, and a second end 131n of the first gas conduit 131 is coupled to a processing chamber 102 and distal to the first gas supply system 120a and the second gas supply system 120b. In some embodiments, heating systems such as the first heating system 140a and the second heating system 140b are distal to the first gas conduit 131.

In some embodiments, the first guiding channel 131a is connected to a first end 131m of the first gas conduit 131 and the first gas supply system 120a, the first heating system 140a is disposed within the first gas supply system 120a, and the first guiding channel 131a provides the first heated gas 103h to the first gas conduit 131. In some embodiments, the second guiding channel 131b is connected to the first end 131m of the first gas conduit 131 and the second gas supply system 120b, the second heating system 140b is disposed within the second gas supply system 120b, and the second guiding channel 131b provides the second heated gas to the first gas conduit 131.

Based on the present disclosure, multiple gas supply systems such as the first gas supply system 120a and the second gas supply system 120b and multiple heating systems such as the first heating system 140a and the second heating system 140b can be implemented. A person ordinarily skilled in the art would readily understand that any suitable number of the gas supply systems may alternatively be utilized, and such arrangements are within the spirit and scope of the present disclosure.

In some embodiments, the apparatus 100d further includes a third gas supply system 120c, a third heating system 140c disposed within the third gas supply system 120c, a fourth gas supply system 120d, a fourth heating system 140d disposed within the fourth gas supply system 120d, a fifth gas supply system 120e, and a fifth heating system 140e disposed within the fifth gas supply system 120e, configured to supply a third heated gas (not shown), a fourth heated gas (not shown) and a fifth heated gas (not shown), respectively, to the first gas conduit 131.

A structure and a configuration of the third gas supply system 120c and the third heating system 140c, the fourth gas supply system 120d and the fourth heating system 140d, and the fifth gas supply system 120e and the fifth heating system 140e are similar to the structure and the configuration of the first gas supply system 120a and the first heating system 140a. In some embodiments, each of the gas supply systems can independently provide gas or stop supplying gas to first gas conduit 131. The first gas supply system 120a, the second gas supply system 120b, the third gas supply system 120c, the fourth gas supply system 120d and/or the fifth gas supply system 120e are configured to provide same or different heated gases.

In some embodiments, a third guiding channel 131c is connected to a first end 131m of the first gas conduit 131 and the third gas supply system 120c. In some embodiments, a fourth guiding channel 131d is connected to the first end 131m of the first gas conduit 131 and the fourth gas supply system 120d. In some embodiments, a fifth guiding channel 131e is connected to the first end 131m of the first gas conduit 131 and the fifth gas supply system 120e. In some embodiments, all the heated gases from the first gas supply system 120a, the second gas supply system 120b, the third gas supply system 120c, the fourth gas supply system 120d and/or the fifth gas supply system 120e are mixed in the first gas conduit 131 to form a mixture. In some embodiments, a temperature of the mixture is higher than a temperature of a first gas provided by the first gas container 121a.

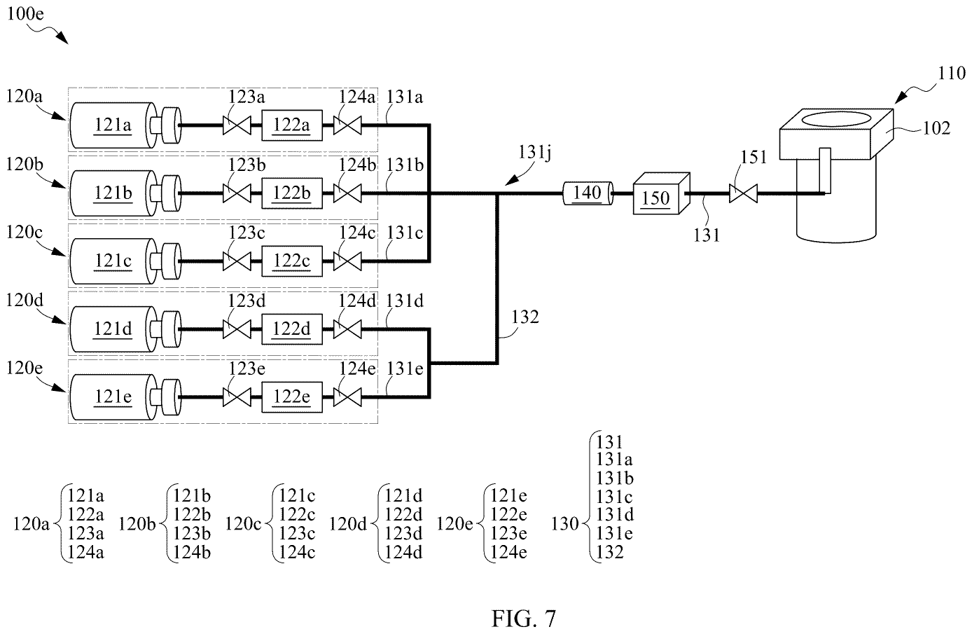

FIG. 7 is a schematic view of an apparatus in accordance with some embodiments of the present disclosure. In some embodiments, an apparatus 100e shown in FIG. 7 is provided. A first gas supply system 120a, a second gas supply system 120b, a third gas supply system 120c, a fourth gas supply system 120d, a fifth gas supply system 120e, a gas regulating system 130, a heating system 140, a storage tank 150 and a processing device 110 illustrated in FIG. 7 are similar to the first gas supply system 120a, the second gas supply system 120b, the third gas supply system 120c, the fourth gas supply system 120d, the fifth gas supply system 120e, the gas regulating system 130, the heating system 140, the storage tank 150 and the processing device 110 illustrated in FIG. 4, respectively, except that the apparatus 100e shown in FIG. 7 further includes a junction point 131j of a first gas conduit 131 and a second gas conduit 132 disposed between and in communication with the junction point 131j of the first gas conduit 131 and the fourth gas supply system 120d.

In some embodiments, a first guiding channel 131a, a second guiding channel 131b, and a third guiding channel 131c are connected to the first gas conduit 131 and are configured to provide gases having a first specific property such as a specific binding energy range.

In some embodiments, the junction point 131j connects the first gas conduit 131 and the second gas conduit 132 and is disposed between the first gas supply system 120a and the heating system 140. In some embodiments, the junction point 131j is disposed between the first guiding channel 131a and the heating system 140.

In some embodiments, the second gas conduit 132 connects the junction point 131j to the fourth gas supply system 120d and the fifth gas supply system 120e. In some embodiments, a fourth guiding channel 131d is connected to the second gas conduit 132 and the fourth gas supply system 120d. In some embodiments, a fifth guiding channel 131e is connected to the second gas conduit 132 and the fifth gas supply system 120e. In some embodiments, the fourth guiding channel 131d and the fifth guiding channel 131e connected to the second gas conduit 131 are configured to provide gases having a second specific property. In some embodiments, the first specific property is different from the second specific property.

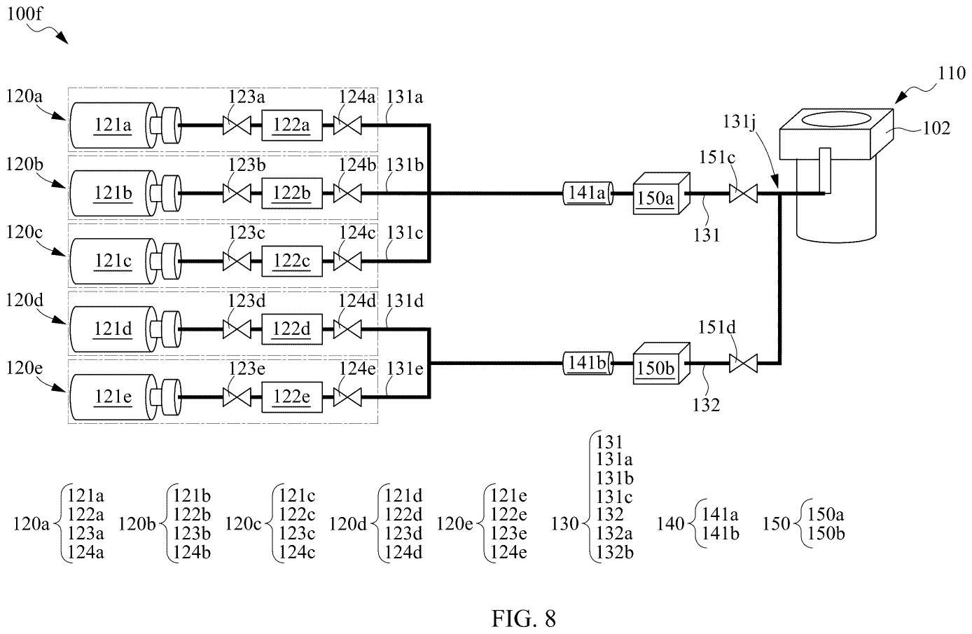

FIG. 8 is a schematic view of an apparatus in accordance with some embodiments of the present disclosure. In some embodiments, an apparatus 100f shown in FIG. 8 is provided. A first gas supply system 120a, a second gas supply system 120b, a third gas supply system 120c, a fourth gas supply system 120d, a fifth gas supply system 120e, a gas regulating system 130 and a processing device 110 illustrated in FIG. 8 are similar to the first gas supply system 120a, the second gas supply system 120b, the third gas supply system 120c, the fourth gas supply system 120d, the fifth gas supply system 120e, the gas regulating system 130 and the processing device 110 illustrated in FIG. 7, respectively, except that a heating system 140, a storage tank 150, and a junction point 131j of the apparatus 100f are different from the heating system 140, the storage tank 150 and the junction point 131j of the apparatus 100e.

In some embodiments, the heating system 140 of the apparatus 100f includes a first heater 141a and a second heater 141b. In some embodiments, the first heater 141a is disposed on the first gas conduit 131 and is configured to provide the first heated gas 103h, a second heated gas, a third heated gas or a first mixture thereof to the processing device 110. In some embodiments, the second heater 141b is disposed on the second gas conduit 132 and is configured to provide a fourth heated gas, a fifth heated gas or a second mixture thereof to the processing device 110. In some embodiments, the first heater 141a is concentrically provided with respect to the first gas conduit 131, and the second heater 141b is concentrically provided with respect to the second gas conduit 132.

In some embodiments, the storage tank 150 includes a first storage chamber 150a and a second storage chamber 150b. The first storage chamber 150a is disposed between the junction point 130j and the first heater 141a, and is configured to store and provide to the processing chamber 102 a first heated gas, a second heated gas, a third heated gas or a first mixture thereof. The second storage chamber 150b is disposed between the junction point 130j and the second heater 141b, and is configured to store and provide to the processing chamber 102 a fourth heated gas, a fifth heated gas or a second mixture thereof. In some embodiments, the first mixture and the second mixture have different compositions, or the first mixture and the second mixture have different temperatures.

In some embodiments, the junction point 131j connects the first gas conduit 131 to the second gas conduit 132 and is disposed between the first heater 141a and the processing chamber 110, and the second gas conduit 132 is disposed between and in communication with the junction point 131j of the first gas conduit 131 and the fourth gas supply system 120d. In some embodiments, the junction point 131j is disposed between the first storage chamber 150a and the processing chamber 102. In some embodiments, the junction point 131j is disposed between the second storage chamber 150b and the processing chamber 102.

In some embodiments, the first gas conduit 131 is in communication with the first gas supply system 120a, the second gas supply system 120b and the third gas supply system 120c, and the second gas conduit 132 is in communication with the fourth gas supply system 120d and the fifth gas supply system 120e.

In some embodiments, a source head valve 151c is disposed between the first storage chamber 150a and the processing device 110. When the source head valve 151c is in an open configuration, the first heated gas, the second heated gas, the third heated gas or the first mixture thereof may flow into the processing chamber 102. In some embodiments, a source head valve 151d is disposed between the second storage chamber 150b and the processing device 110. When the source head valve 151d is in an open configuration, the fourth heated gas, the fifth heated gas or the second mixture thereof may flow into the processing chamber 102.

In some embodiments, closing the source head valve 151c can prevent the first heated gas, the second heated gas, the third heated gas or the first mixture thereof in the first storage chamber 150a from flowing to the processing chamber 102. In some embodiments, closing the source head valve 151d can prevent the fourth heated gas, the fifth heated gas or the second mixture thereof in the second storage chamber 150b from flowing to the processing chamber 102. In some embodiments, the source head valves 151c, 151d can be controlled by a control unit (not shown) and can be opened and closed at a same time (or at different times).

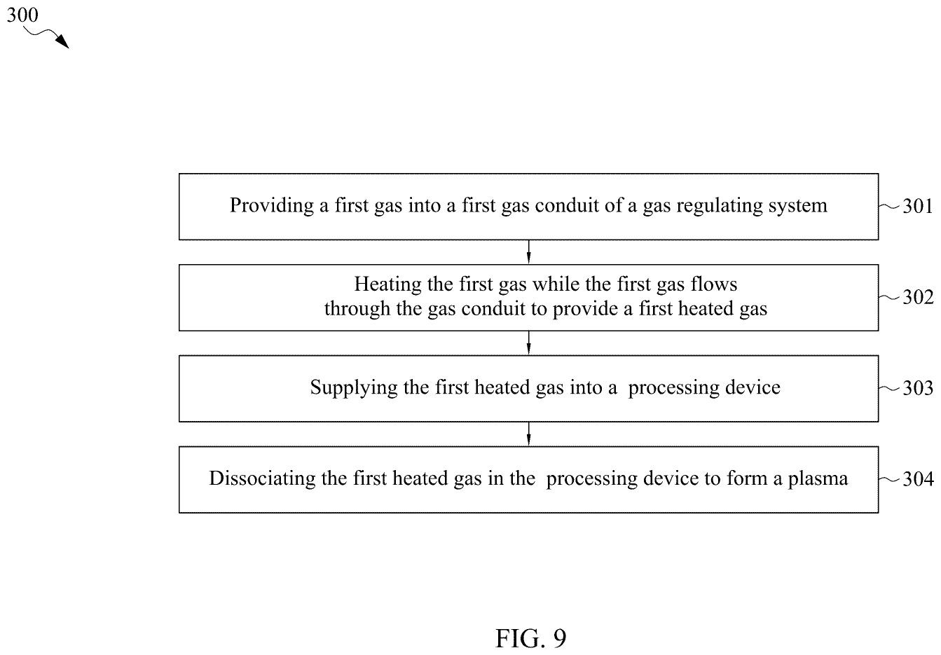

According to some embodiments of the present disclosure, a method 300 for manufacturing a semiconductor structure is disclosed. In some embodiments, the method 300 utilizes an apparatus 100 for manufacturing a semiconductor structure. The method 300 includes a number of operations, and the description and illustration are not deemed as a limitation to the sequence of operations. FIG. 9 is a flowchart of the method 300 in accordance with some embodiments. The method 300 includes a number of operations (301 to 304). Additional steps can be provided before, during, and after the steps shown in FIG. 9, and some of the steps described below can be replaced or eliminated in other embodiments of the method 300. The order of the steps may be interchangeable.

In operation 301, a first gas 103 is provided into a first gas conduit 131 of a gas regulating system 130. In some embodiments, an apparatus 100 shown in FIGS. 1 and 2 is provided. In some embodiments, referring to FIGS. 1, 2 and 9, the first gas 103 is provided by a first gas supply system 120a. In some embodiments, the first gas 103 is provided by a first gas container 121a of the first gas supply system 120a and flows into a first flow controller 122a of the first gas supply system 120a when a first gas container valve 123a of the first gas supply system 120a is opened, and the first gas 103 flows into the first gas conduit 131 of a gas regulating system 130 when a first gate valve 124a of the first gas supply system 120a is opened.

In operation 302, the first gas 103 is heated while the first gas 103 flows through the first gas conduit 131 to provide a first heated gas 103h. In some embodiments, a heating system 140 is provided and disposed on the gas regulating system 130. In some embodiments, the first gas 103 is heated to a first predetermined temperature by the heating system 140 while the first gas 103 flows through the first gas conduit 131.

In operation 303, the first heated gas 103h is supplied into a processing device 110. In some embodiments, the first heated gas 103h is supplied into a processing chamber 102 by the first gas conduit 131.

In operation 304, the first heated gas 103h is dissociated in the processing device 110 to form a plasma. In some embodiments, a power is supplied to the first heated gas 103h in the processing chamber 102 to form the plasma. Because the first heated gas 103h has the predetermined temperature, a power consumption of the processing device 110 of the present disclosure can be reduced by at least 15% and by as much as 45% compared to a processing device using a non-heated gas to form plasma, and a service life of the processing device 110 of the present disclosure can be prolonged by at least 15%. In some embodiments, the plasma is formed within the processing chamber 102.

In some embodiments, an apparatus 100a shown in FIG. 3 is provided for the method 300. In some embodiments, referring to FIGS. 3 and 9, before the first heated gas 103h is supplied into the processing device 110, the first heated gas 103h is stored in a storage tank 150. In some embodiments, the first heated gas 103h is supplied into the processing device 110 from the storage tank 150.

In some embodiments, an apparatus 100b shown in FIG. 4 is provided for the method 300. In some embodiments, referring to FIGS. 4 and 9, the method 300 further includes providing a second gas (not shown) into the first gas conduit 131 of the gas regulating system 130, heating the second gas while the second gas flows through the first gas conduit 131 to provide a second heated gas (not shown), storing the first heated gas 103h and the second heated gas in a storage tank 150 to form a third mixture, and supplying the third mixture into the processing device 110. In some embodiments, the first gas 103 and the second gas have different compositions. In some embodiments, the first heated gas 103h and the second heated gas have different temperatures. In some embodiments, the third mixture has a second predetermined temperature.

In some embodiments, the second gas is provided by a second gas supply system 120b. In some embodiments, the second gas is provided by a second gas container 121b of the second gas supply system 120b and flows into a second flow controller 122b of the second gas supply system 120b when a second gas container valve 123b of the second gas supply system 120b is opened, and the second gas flows into the first gas conduit 131 of a gas regulating system 130 when a second gate valve 124b of the second gas supply system 120b is opened.

In some embodiments, before the third mixture is supplied into the processing device 110, the third mixture is stored in a storage tank 150. In some embodiments, the third mixture is supplied into the processing device 110 from the storage tank 150.

In some embodiments, a third gas is provided into the first gas conduit 131 by a third gas supply system 120c, a fourth gas is provided into the first gas conduit 131 by a fourth gas supply system 120d, and/or a fifth gas is provided into the first gas conduit 131 by a fifth gas supply system 120e. In some embodiments, the third mixture further includes the third gas, the fourth gas, and/or the fifth gas.

In some embodiments, an apparatus 100c shown in FIG. 5 is provided for the method 300. In some embodiments, referring to FIGS. 5 and 9, a first heating system 140a and a first storage tank 150a are provided and disposed between a first gas container 121a and a first flow controller 122a. In some embodiments, after the first gas 103 is heated by the first heating system 140a, the first heated gas 103h is stored in the first storage tank 150a. In some embodiments, the first heated gas 103h in the first storage tank 150a has a third predetermined temperature. In some embodiments, the first heated gas 103h having the third predetermined temperature is supplied into the processing device 110 from the first storage tank 150a, and the first flow controller 122a controls a flow rate of the first heated gas 103h.

In some embodiments, an apparatus 100d shown in FIG. 6 is provided for the method 300. In some embodiments, referring to FIGS. 6 and 9, a second heating system 140b and a second storage tank 150b are provided and disposed between a second gas container 121b and a second flow controller 122b. In some embodiments, after a second gas is heated by the second heating system 140b, the second heated gas is stored in the second storage tank 150b. In some embodiments, the second heated gas in the second storage tank 150b has a fourth predetermined temperature. In some embodiments, the second heated gas having the fourth predetermined temperature is supplied into the processing device 110 from the second storage tank 150b, and the second flow controller 122b controls a flow rate of the second heated gas.

In some embodiments, the first heated gas 103h is supplied in the first gas conduit 131 by a first guiding channel 131a. In some embodiments, the second heated gas is supplied in the first gas conduit 131 by a second guiding channel 131b. In some embodiments, the first heated gas 103h and the second heated gas are supplied to the processing device 110 by the first gas conduit 131 simultaneously or separately. In some embodiments, the first heated gas 103h and the second heated gas are mixed in the first gas conduit 131.

In some embodiments, a third heated gas is provided into the first gas conduit 131 by a third gas supply system 120c and a third heating system 140c, a fourth heated gas is provided into the first gas conduit 131 by a fourth gas supply system 120d and a fourth heating system 140d, and/or a fifth heated gas is provided into the first gas conduit 131 by a fifth gas supply system 120e and a fifth heating system 140e. In some embodiments, the first heated gas, the second heated gas, the third heated gas, the fourth heated gas, and/or the fifth heated gas are mixed in the first gas conduit 131.

In some embodiments, an apparatus 100e shown in FIG. 7 is provided. In some embodiments, referring to FIGS. 7 and 9, the method 300 further includes providing a fourth mixture including the first gas 103, the second gas and/or a third gas into the first gas conduit 131 of the gas regulating system 130, and providing a fifth mixture including a fourth gas and/or a fifth gas into the first gas conduit 131 of the gas regulating system 130.

The method 300 further includes heating the fourth mixture while the first mixture flows through the first gas conduit 131 to provide a first heated mixture, heating the fifth mixture while the fifth mixture flows through the first gas conduit 131 to provide a second heated mixture, storing the first heated mixture and the second heated mixture in a storage tank 150 to form a sixth mixture, and supplying the sixth mixture into the processing device 110. In some embodiments, the fourth mixture and the fifth mixture are heated together in the first gas conduit 131. In some embodiments, the fourth mixture and the fifth mixture are supplied to the processing device 110 simultaneously or separately. In some embodiments, the fourth mixture and the fifth mixture have different compositions. In some embodiments, the first heated mixture and the second heated mixture have different temperatures. In some embodiments, the sixth mixture has a fifth predetermined temperature.

In some embodiments, a second gas conduit 132 is provided and in communication with a junction point 131j of the first gas conduit 131. In some embodiments, the second gas conduit 132 supplies the fifth mixture into the first gas conduit 131.

In some embodiments, an apparatus 100e shown in FIG. 8 is provided for the method 300. In some embodiments, referring to FIGS. 8 and 9, the method 300 further includes providing a seventh mixture including the first gas 103, the second gas and/or a third gas into the first gas conduit 131 of the gas regulating system 130 and heating the seventh mixture by the first heater 141a to provide a third heated mixture. The method 300 further includes providing the eighth mixture including the fourth gas and/or a fifth gas into the second gas conduit 132 of the gas regulating system 130 and heating the eighth mixture by the second heater 141b to provide a fourth heated mixture.

The method 300 further includes storing the third heated mixture in a first storage tank 150a and storing the fourth heated mixture in a second storage tank 150b. In some embodiments, the third heated mixture and the fourth heated mixture are supplied to the processing device 110 simultaneously or separately.

In some embodiments, a second gas conduit 132 is provided and is in communication with a junction point 131j of the first gas conduit 131 and the second heater 141b. In some embodiments, the second gas conduit 132 supplies the fourth heated mixture into the first gas conduit 131.

In some embodiments, the third heated mixture and the fourth heated mixture form a ninth mixture in the junction point 131j, and the ninth mixture has a fifth predetermined temperature.

In some embodiments, the method 300 further includes storing the third heated mixture in the first storage tank 150a and storing the fourth heated mixture in the second storage tank 150b before the formation of the ninth mixture. In some embodiments, before the third heated mixture is supplied into the processing device 110, the third heated mixture is stored in a first storage tank 150a. In some embodiments, before the fourth heated mixture is supplied into the processing device 110, the fourth heated mixture is stored in a second storage tank 150b.

In some embodiments, a first source head valve 151a disposed between the processing chamber 110 and the first heater 141a is provided. In some embodiments, the first source head valve 151a is in an open configuration to allow the third heated mixture to flow toward the processing device 110 through the first gas conduit 131. In some embodiments, a second source head valve 151b disposed between the processing chamber 110 and the second heater 141b is provided. In some embodiments, the second source head valve 151b is in an open configuration to allow the fourth heated mixture to flow toward the processing device 110 through the first gas conduit 131 and the second gas conduit 132.

In accordance with some embodiments of the disclosure, an apparatus for manufacturing a semiconductor structure includes a processing chamber configured to form a plasma; a first gas supply system configured to supply a first gas to the processing chamber; a gas conduit disposed between and in communication with the processing chamber and the first gas supply system; and a heating system disposed on the gas conduit and configured to heat the first gas flowing through the gas conduit and to provide a first heated gas to the processing chamber.

In accordance with some embodiments of the disclosure, an apparatus for manufacturing a semiconductor structure includes a processing chamber configured to extract an ion beam; a first gas supply system configured to supply a first gas to the processing chamber; a second gas supply system configured to supply a second gas to the processing chamber; a gas regulating system connecting the processing chamber to the first gas supply system and the second gas supply system; and a heating system disposed on the gas regulating system and configured to heat the first gas and the second gas flowing through the gas regulating system and to provide a first heated gas and a second heated gas.

In accordance with some embodiments of the disclosure, a method for manufacturing a semiconductor structure includes providing a first gas into a first gas conduit of a gas regulating system; heating the first gas while the first gas flows through the first gas conduit to provide a first heated gas; supplying the first heated gas into a processing device; and dissociating the first heated gas in the processing device to form a plasma.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An apparatus for manufacturing a semiconductor structure, comprising:
a processing chamber configured to form a plasma;
a first gas supply system configured to supply a first gas to the processing chamber;
a gas conduit disposed between and in communication with the processing chamber and the first gas supply system; and
a heating system disposed on the gas conduit and configured to heat the first gas flowing through the gas conduit and to provide a first heated gas to the processing chamber.

2. The apparatus of claim 1, wherein the first gas supply system includes a first gas source and a first flow controller connected to the first gas source through the gas conduit.

3. The apparatus of claim 2, wherein the heating system is disposed between the first flow controller and the processing chamber.

4. The apparatus of claim 2, wherein the heating system is disposed between the first gas source and the first flow controller.

5. The apparatus of claim 1, further comprising:
a storage tank disposed between the processing chamber and the heating system, wherein the storage tank is in communication with the gas conduit and configured to store the first heated gas.

6. The apparatus of claim 1, further comprising:
a second gas supply system configured to supply a second gas to the processing chamber;
a first guiding channel connected to a first end of the gas conduit and the first gas supply system; and
a second guiding channel connected to the first end of the gas conduit and the second gas supply system,
wherein a second end of the gas conduit is connected to the processing chamber, the first end is opposite to the second end, and the heating system is configured to heat the second gas flowing through the gas conduit and to provide a second heated gas to the processing chamber.

7. The apparatus of claim 6, further comprising:
a storage tank dispose between the processing chamber and the heating system, wherein the storage tank is in communication with the gas conduit and configured to mix the first heated gas and the second heated gas therein.

8. The apparatus of claim 1, wherein the processing chamber includes a cathode and a filament.

9. An apparatus for manufacturing a semiconductor structure, comprising:
a processing chamber configured to extract an ion beam;
a first gas supply system configured to supply a first gas to the processing chamber;
a second gas supply system configured to supply a second gas to the processing chamber;
a gas regulating system connecting the processing chamber to the first gas supply system and the second gas supply system; and
a heating system disposed on the gas regulating system and configured to heat the first gas and the second gas flowing through the gas regulating system and to provide a first heated gas and a second heated gas.

10. The apparatus of claim 9, further comprising:
a storage tank disposed between the processing chamber and the heating system,
wherein the storage tank is in communication with the gas regulating system and is configured to receive the first heated gas and the second heated gas, and to provide a mixture of the first heated gas and the second heated gas to the processing chamber.

11. The apparatus of claim 9, wherein the gas regulating system includes:
a first gas conduit disposed between and in communication with the processing chamber and the first gas supply system, wherein the first gas conduit has a junction point, and
a second gas conduit disposed between and in communication with the junction point of the first gas conduit and the second gas supply system.

12. The apparatus of claim 11, wherein the junction point is disposed between the first gas supply system and the heating system.

13. The apparatus of claim 11, further comprising:
a third gas supply system configured to supply a third gas to the first gas conduit; and
a storage tank disposed between the processing chamber and the heating system,
wherein the heating system is configured to provide the first heated gas, the second heated gas and a third heated gas, and the storage tank is configured to store and provide to the processing chamber a mixture of the first heated gas, the second heated gas and the third heated gas.

14. The apparatus of claim 11, wherein the heating system further comprises:
a first heater disposed on the first gas conduit configured to provide the first heated gas; and
a second heater disposed on the second gas conduit configured to provide the second heated gas,
wherein the junction point is disposed between the first heater and the processing chamber.

15. The apparatus of claim 14, further comprising:
a third gas supply system configured to supply a third gas to the first gas conduit; and
a storage tank disposed between the processing chamber and the heating system,
wherein the storage tank includes a first storage chamber and a second storage chamber, the first storage chamber is disposed between the junction point and the first heater and is configured to provide a mixture of the first heated gas and a third heated gas to the processing chamber, and the second storage chamber is disposed between the junction point and the second heater and is configured to store the second heated gas.

16. The apparatus of claim 9, wherein the apparatus further includes an implant tool to use the ion beam.

17. A method for manufacturing a semiconductor structure, comprising:
providing a first gas into a first gas conduit of a gas regulating system;
heating the first gas while the first gas flows through the first gas conduit to provide a first heated gas;
supplying the first heated gas into a processing device; and
dissociating the first heated gas in the processing device to form a plasma.

18. The method of claim 17, further comprising:
providing a second gas into the first gas conduit of the gas regulating system;
heating the second gas while the second gas flows through the first gas conduit to provide a second heated gas;
storing the first heated gas and the second heated gas in a storage tank to form a mixture; and
supplying the mixture into the processing device,
wherein the first gas and the second gas have different compositions, or the first heated gas and the second heated gas have different temperatures.

19. The method of claim 17, further comprising:
providing a second gas into a second gas conduit of the gas regulating system;
heating the second gas while the second gas flows through the second gas conduit to provide a second heated gas;
storing the first heated gas in a first storage chamber before the first heated gas is supplied to the processing device;
storing the second heated gas in a second storage chamber, and
supplying the second heated gas into the processing device.

20. The method of claim 19, wherein the first heated gas and the second heated gas are supplied to the processing device simultaneously or separately.
